(19) United States
(12) Patent Application Publication
(10) Pub. No.: US 2007/0090521 A1
(43) Pub. Date: Apr. 26, 2007

(54) Circuit device and method of manufacturing the same

(75) Inventors: Hideo Imaizumi, Gunma (JP); Takuji Kato, Saitama (JP); Kenichi Nakajima, Saitama (JP); Masami Harigai, Tochigi (JP); Masachika Kuwata, Gunma (JP); Isao Ochiai, Gunma (JP); Makoto Tsubonoya, Gunma (JP); Katsuhiko Shibusawa, Gunma (JP); Iwao Takase, Gunma (JP)

Correspondence Address: FISH & RICHARDSON P.C., P.O. BOX 1022, MINNEAPOLIS, MN, 55440-1022, US

(73) Assignees: SANYO ELECTRIC CO., LTD., Osaka (JP); KANTO SANYO SEMICONDUCTORS CO., LTD., Gumma (JP)

(21) Appl. No.: 10/569,788

(22) PCT Filed: Sep. 1, 2004
(86) PCT No.: PCT/JP04/13002

§ 371 Date: Oct. 24, 2006

(30) Foreign Application Priority Data
Sep. 2, 2003 (JP) 2003-310763

(51) Int. Cl. H01L 23/34

(52) U.S. Cl. 257/723

(57) ABSTRACT

It is an object of the present invention to provide a circuit device in which a plurality of circuit elements including a circuit element having a hollow inside are sealed with resin, and to provide a method of manufacturing the same. A circuit device (10) has a first circuit element (13A) having a hollow inside and a plurality of second circuit elements (13B) electrically connected to the first circuit element (13A). The first and second circuit elements (13A) and (13B) are sealed with sealing resin (15). The distances by which the first circuit element (13A) is separated from the second circuit elements (13B) are longer than those by which the second circuit elements (13B) are separated from each other.

### BACKGROUND OF THE INVENTION

Priority is claimed to Japanese Patent Application Number JP2003-310763 filed on Sep. 2, 2003, the disclosure of which is incorporated herein by reference in its entirety.

1. Field of the Invention

The present invention relates to a circuit device and a method of manufacturing the same. In particular, the present invention relates to a circuit device in which a plurality of circuit elements are sealed with resin, and to a method of manufacturing the same.

2. Description of the Related Art

With reference to FIG. 6, the structure of a known-type SAW filter device 100 will be described. FIG. 6 is a cross-sectional view of the SAW filter device 100.

Referring to FIG. 6, a surface acoustic wave (SAW) filter element 103 is fixed to the top of a support board 101. The SAW filter 103 is connected through fine metal wires 104 to electrodes 102 formed on the surface of the support board. The electrodes 102 penetrates the support board 101 to be connected to backside electrodes 106 formed on the backside of the support board 101. Further, the SAW filter element 103 has electrodes on the surface thereof. The SAW filter 103 has been sealed with a casing member 105 in order to ensure gaps between the electrodes.

Moreover, referring to FIG. 7, the above-described SAW filter device 100 and other circuit elements have been mounted on a mount board PS to constitute a module having a predetermined function. Here, the other circuit elements include a semiconductor device 110 in which a semiconductor element 111 is sealed with resin 112, a chip capacitor CC, and a chip resistor CR. These circuit elements have been connected to each other using a conducting pattern formed on the mount board PS.

However, the above-described SAW filter device 100 has been sealed with the casing member 105 in order to ensure the gaps between the electrodes of the SAW filter device 100. This has caused the problem that the SAW filter device 100 itself is large. Further, this SAW filter device 100 and the semiconductor device 110 have been mounted as individual circuit elements on the mount board. Accordingly, there has been the problem that a mounting process requires a lot of labor and that cost is increased.

### SUMMARY OF THE INVENTION

The present invention has been accomplished in light of the above-described problems. The present invention provides a circuit device in which a circuit element having a hollow inside is sealed with resin, and the invention also provides a method of manufacturing the same.

The present invention also provides a circuit device that includes a first circuit element having a hollow inside, a plurality of second circuit elements electrically connected to the first circuit element, and sealing resin for covering the first and second circuit elements. Here, the distances by which the first circuit element is separated from the second circuit elements are longer than those by which the second circuit elements are separated from each other.

The present invention also provides a circuit device that includes a first circuit element having a hollow inside, a second circuit element electrically connected to the first circuit element, and sealing resin for covering the first and second circuit elements. Here, the first circuit element is located closer to a peripheral portion of the sealing resin than the second circuit element is.

The present invention further provides a circuit device that includes a first circuit element which is fixed to a first land and which has a hollow inside, a second circuit element fixed to a second land located in a vicinity of a central portion away from the first land, a first lead of which one end is led out to an outside and of which other end is connected to any one of the first and second circuit elements, a second lead for connecting the first and second circuit elements, and sealing resin for sealing the circuit elements and the leads.

The present invention further provides a circuit device-manufacturing method that includes placing a first circuit element having a hollow inside and a second circuit element electrically connected to the first circuit element in a cavity of a molding die, and sealing the first and second circuit elements with resin by filling sealing resin from a gate into the cavity. Here, the first circuit element is located farther away from the gate than the second circuit element is.

### BRIEF DESCRIPTION OF THE DRAWINGS

FIG. 1A is a perspective view for explaining a circuit device according to an embodiment of the present invention;

FIG. 1B is a plan view for explaining the circuit device according to the embodiment of the present invention;

FIG. 2A is a conceptual diagram for explaining the circuit device according to the embodiment of the present invention;

FIG. 2B is a cross-sectional view for explaining the circuit device according to the embodiment of the present invention;

FIG. 3A is a plan view for explaining the circuit device according to the embodiment of the present invention;

FIG. 3B is a characteristic diagram for explaining the circuit device according to the embodiment of the present invention;

FIG. 3C is a perspective view for explaining the circuit device according to the embodiment of the present invention;

FIG. 4 is a plan view for explaining the circuit device according to the embodiment of the present invention;

FIG. 5A is a cross-sectional view for explaining a method of manufacturing the circuit device according to the embodiment of the present invention;

FIG. 5B is a cross-sectional view for explaining the method of manufacturing the circuit device according to the embodiment of the present invention;

FIG. 5C is a characteristic diagram for explaining the method of manufacturing the circuit device according to the embodiment of the present invention;

FIG. 6 is a cross-sectional view for explaining a conventional circuit device; and

FIG. 7 is a cross-sectional view for explaining the conventional circuit device.

### DETAILED DESCRIPTION OF THE PREFERRED EMBODIMENTS

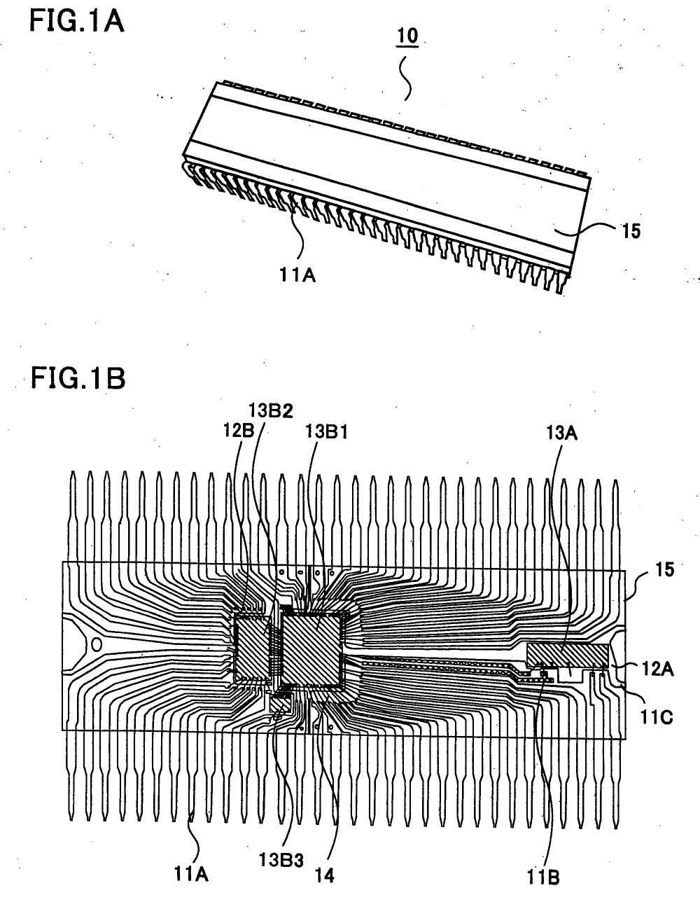

With reference to FIGS. 1A and 1B, a detailed structure of a circuit device according to an embodiment of the present invention will be described. FIG. 1A is a perspective view of a circuit device 10 of the preferred embodiment, and FIG. 1B is a plan view thereof. Referring to these drawings, the circuit device 10 has a first circuit element 13A having a hollow inside, and a plurality of second circuit elements 13B electrically connected to the first circuit element 13A. The first and second circuit elements 13A and 13B are sealed with sealing resin 15. Further, the distances by which the first circuit element 13A is separated from the second circuit elements 13B are longer than those by which the second circuit elements 13B are separated from each other. Each of the above-described components will be described below.

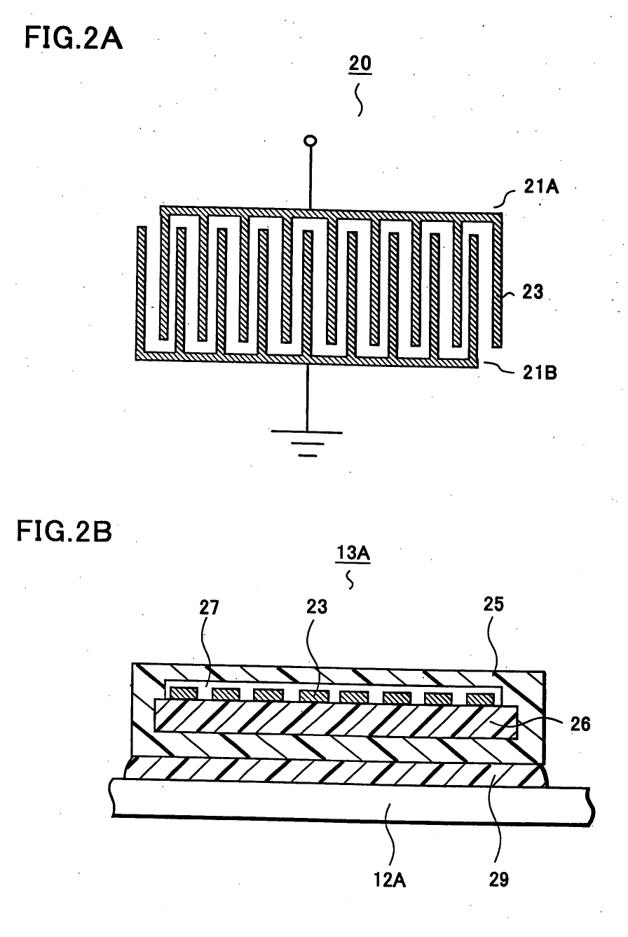

The first circuit element 13A is a circuit element having a hollow (space) inside thereof, and is fixed to the top of a first land 12A here, which is formed in an end portion of the circuit device 10 in the longitudinal direction. Moreover, the first circuit element 13A is located to be positioned in the vicinity of an end portion of the sealing resin 15 in the longitudinal direction, which the sealing resin 15 is formed into a long and narrow shape. Furthermore, the distances by which the first circuit element 13A is separated from the second circuit elements are longer than those by which the second circuit elements 13B are separated from each other. Specifically, as the first circuit element, a surface acoustic wave filter (SAW filter) can be adopted. Details of the first circuit element 13A which is a SAW filter will be described with reference to FIGS. 2A and 2B.

Moreover, the first circuit element 13A is electrically connected to leads 11 through fine metal wires 14. Further, a signal from the outside is inputted into the first circuit element 13A through first leads 11A, and an electrical signal in a desired frequency band is extracted by the first circuit element 13A; which is a SAW filter. The electrical signal extracted by the first circuit element is inputted into a second circuit element 13B1 through second leads 11B.

The leads 11 include the first leads 11A and second leads 11B. On ends of the first leads 11A are led out from the sealing resin to extend to the outside, thus forming external terminals. The other end of each first leads 11A extends to the vicinity of any of the first and second circuit elements 13A and 13B and is electrically connected to the relevant element through the fine metal wire 14. Specifically, one ends of the first leads 11A are led out from opposite sides of the sealing resin 15 in the longitudinal direction at regular intervals, thus forming the external terminals. Further, the other ends of the first leads 13A extend to approach the plurality of second circuit elements 13B located in the central portion. Accordingly, the first leads 11A extend approximately radially from the periphery of the second circuit elements 13B to the outside. Moreover, ends of some of the first leads 11A extend to the vicinity of the first circuit element 13A. Referring to FIG. 1A, the portions of the first leads 11A which are led out to the outside may be bent downward.

The second leads 11B has the function of electrically connecting the circuit elements incorporated in the circuit device 10. Here, the second leads 11B extend from the vicinity of the first circuit element 13A located in the peripheral portion to the vicinity of the second circuit element 13B1 located in the central portion. Further, both of these circuit elements are electrically connected by means of the fine metal wires 14 and the second leads 11B. That is, an electrical signal inputted from the outside is filtered by the first circuit element 13A, which is a SAW filter. Moreover, the extracted electrical signal in a desired frequency band is supplied from the first circuit element 13A to the second circuit element 13B1 through the second leads 11B. Here conceivable electrical signals inputted into the SAW filter are signals received through antennas, which include a video signal, a voice signal, a television signal, and the like.

The second circuit elements 13B are fixed to second lands 12B formed in the vicinity of the central portion of the circuit device 10. Here, the second circuit elements 13B include three semiconductor elements. Specifically, the second circuit element 13B1 is connected to the first circuit element 13A through the second leads 11B, and processes a signal filtered by the first circuit element 13A. As this signal, a video signal, a voice signal, or the like is adopted.

A second circuit element 13B2 is directly connected to the second circuit element 13B1 through the fine metal wires 14. This second circuit element 13B2 has a storage unit including a ROM or a RAM. Setting information and the like, which are different for each user, are stored in this storage unit. For this setting information, a method and the like of displaying a channel of a television can be considered. Further, a circuit for performing a closed-caption TV control function, which is a subtitle function of a television, may be formed in the second circuit element 13B2. Other than this, functions other than image and voice control can be integrated onto the second circuit element 13B2.

A second circuit element 13B3 is electrically connected through the fine metal wires 14 to the second circuit element 13B1 for processing a signal. For this second circuit element 13B3, a CCD which functions as a delay element can be adopted. To be specific about the operation of the second circuit element 13B3, an inputted electrical signal is converted into an electric charge, the electric charge signal is propagated using a clock, and the propagated electric charge signal is converted into a voltage.

The above-described second circuit element 13B1 is mounted on a land different from that on which the second circuit elements 13B2 and 13B3 are mounted. That is, the second land 12B on which the second circuit element 13B1 is mounted and the second land 12B on which the second circuit elements 13B2 and 13B3 are mounted are electrically isolated from each other. This structure makes it possible to prevent clock noise occurring in the second circuit element 13B2, which is a microcomputer, from adversely affecting the second circuit element 13B1, which is an element for processing a signal.

Moreover, electrodes formed on the surface of the second circuit element 13B1 and electrodes formed on the surface of the second circuit element 13B2 are electrically connected through the fine metal wires 14. Further, electrodes formed on the surface of the second circuit element 13B1 and electrodes formed on the surface of the second circuit element 13B3 are electrically connected through the fine metal wires 14.

Referring to FIGS. 2A and 2B, details of the first circuit element 13A, which is a SAW filter, will be described. FIG. 2A is a conceptual diagram showing the structure of SAW filter 20, and FIG. 2B is a cross-sectional view of the first circuit element 13A in which the SAW filter is formed.

With reference to FIG. 2A, a basic structure of the SAW filter will be described. In the SAW filter, a SAW is excited or received using an interdigital transducer (hereinafter abbreviated to IDT) in which electrode fingers 23 as shown in this drawing interlock each other. The SAW filter 20 is formed of at least one excitation IDT 21A and one receiving IDT 21B. The product of the frequency response of the excitation IDT 21A and that of the receiving IDT 21B approximately becomes the frequency response of the SAW filter. That is, the intervals between the electrode fingers 23 extending from the excitation IDT 21A and the receiving IDT 21B determine the frequency response of the SAW filter.

With reference to FIG. 2B, the structure of the first circuit element in which the above-described SAW filter is incorporated will be described. The first circuit element 13A has a piezoelectric substrate 26 inside, which is made of piezoelectric material and which is used as a base substrate. The electrode fingers 23 constituting the IDTs are formed on the surface of this piezoelectric substrate 26. Further, a hollow 27 is formed on the surface of the piezoelectric substrate 26 with sealing resin 25, and electrode fingers 28 are contained in this hollow 27. This hollow is very important in maintaining characteristics of the SAW filter.

The first circuit element 13A having the above-described structure is fixed to the first land 12A with an adhesive 29. Here, using Ag paste as the adhesive 29 is suitable. That is, characteristics of the first circuit element 13A, which is a SAW filter, can be improved. This is considered to be because the thermal expansion coefficient of Ag paste is close to the thermal expansion coefficient of the first circuit element 13A.

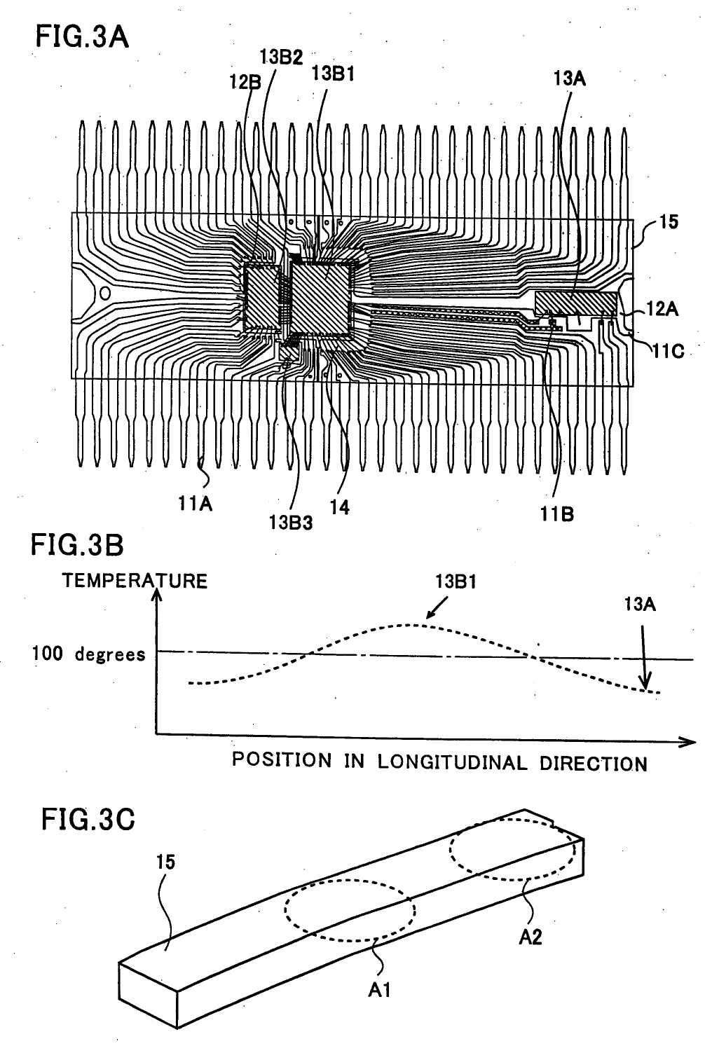

Next, with reference to FIGS. 3A to 3C, the structure of the circuit device 10 which is for minimizing the influence of temperature change in usage on the first circuit element 13A. FIG. 3A is a cross-sectional view of the circuit device 10, FIG. 3B is a characteristic diagram showing a temperature distribution, and FIG. 3C is a conceptual diagram showing an amount of change in deformation of the circuit device 10 due to temperature change.

Referring to FIG. 3A, the second circuit elements 13B which include a plurality of elements including a semiconductor element for processing a signal are fixed to the vicinity of the central portion in the longitudinal direction. Specifically, the three second circuit elements 13B1, 13B2, and 13B3 are located close to each other. Further, the first circuit element 13A, which is a SAW filter, is separated from the second circuit elements 13B and located in the vicinity of an end portion (vicinity of the right end here) of the circuit device 10 in the longitudinal direction. Specifically, the distances by which the first circuit element 13A is separated from the second circuit elements 13B are set to be longer than those by which the second circuit elements 13B are separated from each other.

With reference to FIG. 3B, the temperature distribution of the circuit device in the longitudinal direction in the case where the incorporated circuit elements generate heat due to temperature change in usage will be described. The horizontal axis of this characteristic diagram represents a position in the circuit device 10 in the longitudinal direction. That is, the central portion of the horizontal axis represents the central portion of the circuit device 10 in the longitudinal direction. Further, the vertical axis of this characteristic diagram represents temperature.

Referring to this characteristic diagram, the temperature in the vicinity of the central portion of the circuit device 10 where the plurality of second circuit elements 13 are located exhibits the highest temperature (approximately 120 degrees), and the vicinities of both ends in the longitudinal direction exhibit the lowest temperature (approximately 70 degrees).

Among the circuit elements sealed with the sealing resin 15, the second circuit element 13B1 for processing image and voice signals is an element generating the largest amount of heat. Specifically, this second circuit element 13B1 requires the largest amount of power among the incorporated elements, and generates heat at 130 degrees or more in usage. The second circuit elements 13B2 and 13B3 themselves which are adjacent to the second circuit element 13B1 generate a small amount of heat in. However, the second circuit elements 13B2 and 13B3 are heated by the conduction of heat from the second circuit element 13B1. Specifically, the second circuit elements 13B2 and 13B3 are heated to approximately 110 degrees. However, these circuit elements are semiconductor elements, and therefore can perform the operations thereof without problems even at such high temperature.

The first circuit element 13A is a passive element, and therefore generates a small amount of heat in itself. Furthermore, since the first circuit element 13A is located in the vicinity of an end portion, the amount of heat conduction from the second circuit element 13B1 which is accompanied by heat generation can be reduced. Accordingly, even in usage, the temperature of the first circuit element 13A, which is a SAW filter, can be suppressed to approximately 70 degrees. This makes it possible to inhibit a deterioration of characteristics and a malfunction of the first circuit element 13A due to the heat generation of the second circuit elements 13B.

With reference to FIG. 3C, a deformation of the circuit device 10 associated with the above-described heat generation of the second circuit elements 13B will be described. This drawing is a conceptual diagram showing the amount of deformation of the sealing resin in the case where the circuit elements incorporated in the sealing resin 15 generate heat in usage. In this drawing, the amount of deformation in the vertical direction is shown with emphasis.

A first region A1 shown in this drawing represents the vicinity of the central portion of the sealing resin 15 in the longitudinal direction. As described previously, the second circuit element 13B1, which is an element accompanied by heat generation, is located in this first region A1. Accordingly, the sealing resin in this region exhibits the amount of deformation according to the amount of heat generation. Specifically, the sealing resin in the first region A1 exhibits. deformation curved in an upward direction. However, the amount of deformation in this first region A1 is at a level in which the second circuit elements 13B incorporated in this region are not adversely affected.

A second region A2 represents an end portion of the sealing resin 15 in the longitudinal direction, and the first circuit element 13A is incorporated in this region. As described previously, the temperature of this second region A2 is low compared to the above-described first region A1. Accordingly, the amount of deformation in the second region A2 is also small compared to that in the first region A1. This makes it possible to prevent deformation associated with temperature rise in usage from adversely affecting the first circuit element 13A, which is a SAW filter. Specifically, it is possible to prevent the hollow formed inside the first circuit element 13A, which is a SAW filter, from being collapsed due to deformation associated with temperature rise.

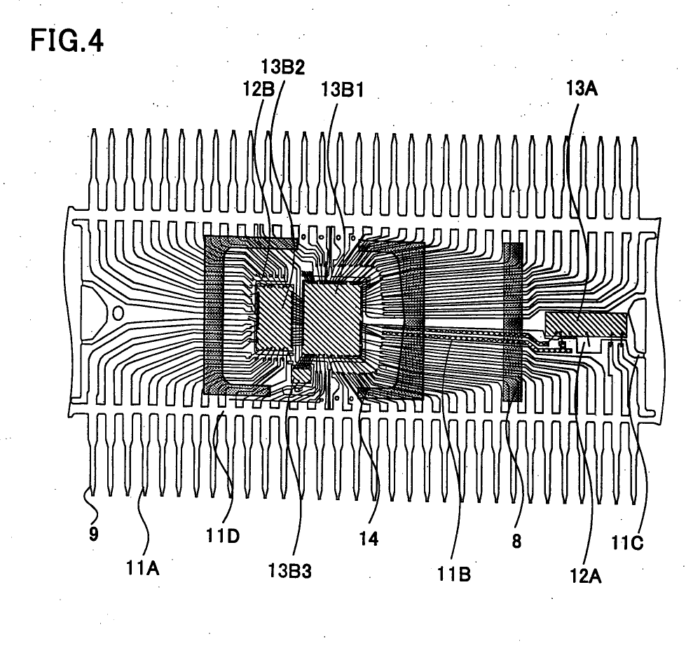

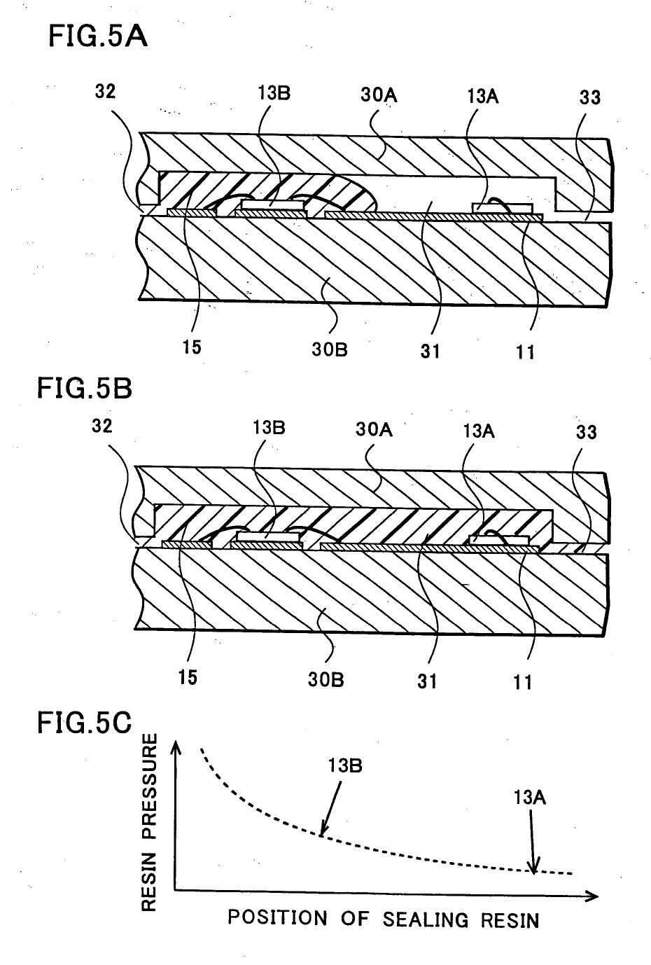

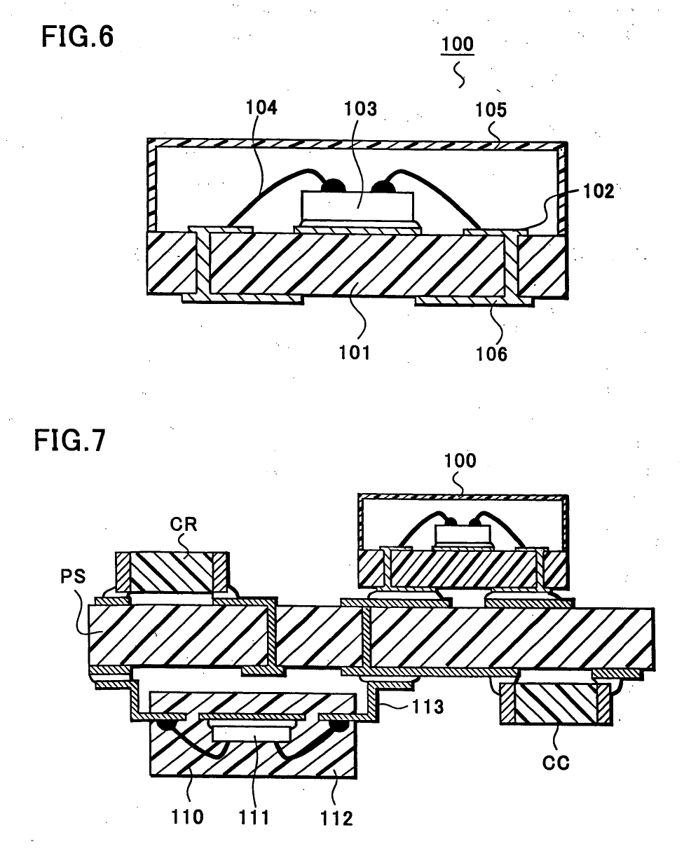

Next, with reference to FIGS. 4 to 5C, a method of manufacturing the above-described circuit device 10 will be described with a focus on a sealing step. The method of manufacturing the circuit device 10 includes the steps of placing the first circuit element 13A having the hollow inside and the second circuit elements 13B electrically connected to the first circuit element 13A in a molding die 30, and sealing the first and second circuit elements 13A and 13B with resin by filling the sealing resin 15 from a gate 32 into a cavity 31 constituted by the molding die 30, whereby the first circuit element 13A is located farther away from the gate 32 than the second circuit elements 13B are.

First, referring to FIG. 4, the first leads 11A and the second leads 11B are formed through a punching or etching step. Here, the leads 11 are supplied as a lead frame 9 having the form of one plate, using tie bars 11D and support leads 1C. Further, the second leads 11B are electrically and mechanically independent of other portions of the lead frame, and therefore mechanically supported by a support sheet 8 made of a resin-based adhesive sheet. Then, the placement of the circuit elements 13 and electrical connection using the fine metal wires 14 are performed.

FIG. 5A is a cross-sectional view of the molding die 30 in the process of performing resin filling, FIG. 5B is a cross-sectional view of the molding die 30 after resin filling has been performed, and FIG. 5C is a characteristic diagram showing change in resin pressure.

Next, referring to FIG. 5A, the lead frame 9 is set on a lower die 30B of the molding die. At this time, the first circuit element 13A is located farther away from the gate 32 than the second circuit elements 13B are. Here, the first circuit element 13A is located in the vicinity of an air vent 33. After the leads 11 have been set in the die, the cavity 31 is constituted by interlocking an upper die 30A with the lower die 30B. Then, the sealing resin 15 is filled into the cavity 31 from the gate 32. In accordance with the amount of the filled resin, air in the cavity 31 is released from the air vent 33 to the outside. As the sealing resin, any of thermosetting resin and thermoplastic resin can be adopted, but thermoplastic resin is more suitable.

Next, referring to FIG. 5B, the cavity 31 is filled with the sealing resin by continuously performing resin filling from the gate 32, thus sealing the leads 11, the circuit elements 13, and the fine metal wires 14. Resin sealing is performed through the above-described step. Moreover, resin sealing can be performed without collapsing the hollow formed in the first circuit element 13A, which is a SAW filter.

With reference to FIG. 5C, how resin sealing is performed without adversely affecting the first circuit element 13A will be described. The horizontal axis of this drawing represents a position in the cavity in the longitudinal direction, and the vertical axis thereof represents the sealing pressure of the filled resin.

Thermosetting resin used in the present application has the property of melting to become less viscous when heated, becoming more viscous by thermal curing when further heated, and progressing to further curing with time. Referring to this drawing, the sealing resin immediately after injected from the gate 32 has a low viscosity and therefore has a high resin pressure. Further, the sealing resin moves from the gate 32 in the direction of the air vent 33 inside the cavity 31, whereby resin curing proceeds and the resin pressure of the sealing resin 15 is reduced. This is because the curing of the sealing resin 15 moving but staying inside the cavity 31 proceeds due to the fact that the temperature of the die 30 is higher than the glass transition temperature of the sealing resin, which is thermosetting resin.

From the above description, it can be seen that the resin pressure of the sealing resin decreases inside the cavity 31 as the distance from the gate 32 increases. Accordingly, it can be seen that the resin pressure acting on the first circuit element 13A provided at the position opposite to the position where the gate 32 is provided is very low inside the cavity 31. Thus, even in the case where transfer molding in which the filling pressure of resin is high has been performed, it is possible to prevent characteristics of the first circuit element 13A, which is a SAW filter, from being deteriorated due to the filling pressure of the resin.

After the above-described steps have been finished, the circuit device 10 as shown in FIGS. 1A and 1B is completed through the step of shaping the leads and other steps.

According to the embodiment of the present invention, the following effects can be obtained.

The embodiment of the present invention has the first circuit element in which the hollow is formed, and the plurality of second circuit elements. Here, the distances by which the first circuit element is separated from the second circuit elements are set to be longer than those by which the second circuit elements are separated from each other. Accordingly, it is possible to prevent heat generated in the second circuit elements from being excessively conducted to the first circuit element. Accordingly, it is possible to prevent thermal stress from causing deformation in the internal space of the first circuit element 13A and deterioration in characteristics of the first circuit element 13A, which is a SAW filter.

In the manufacturing method, in the step of performing resin sealing, the first circuit element is located farther away from the gate than the second circuit elements are. Accordingly, the deformation of the internal space of the first circuit element 13A due to a resin sealing pressure can be inhibited.

1. A circuit device comprising:
a first circuit element having a hollow inside;
a plurality of second circuit elements electrically connected to the first circuit element; and
sealing resin for covering the first and second circuit elements,
wherein the distances by which the first circuit element is separated from the second circuit elements are longer than those by which the second circuit elements are separated from each other.

2. The circuit device according to claim 1, wherein the second circuit elements are located closer to a central portion of the sealing resin than the first circuit element is.

3. The circuit device according to claim 1, wherein the first circuit element is located closer to a peripheral portion of the sealing resin than the second circuit elements are.

4. The circuit device according to claim 1, wherein the first circuit element is a SAW filter.

5. A circuit device comprising:
a first circuit element having a hollow therein;
a plurality of second circuit elements electrically connected to the first circuit element; and
a sealing resin covering the first and second circuit elements,
wherein the first circuit element is disposed in a more peripheral area of the sealing resin than the second circuit elements, and a separated distance between the first and second circuit elements is longer than a separated distance between the second circuit elements.

6. The circuit device according to claim 5, wherein the first circuit element is located in a vicinity of an end portion of the sealing resin in a longitudinal direction, and the second circuit element is located in a vicinity of a central portion of the sealing resin in the longitudinal direction.

7. The circuit device according to claim 5, further comprising:
the plurality of second circuit elements,
wherein the distances by which the first circuit element is separated from the second circuit elements are longer than those by which the second circuit elements are separated from each other.

8. The circuit device according to claim 5, wherein the first circuit element is a SAW filter.

9. A circuit device, comprising:
a first circuit element fixed to a first land and having a hollow therein;
a second circuit element separated from the first land and fixed to a second land disposed in a vicinity of a central area;
a first lead whose one end is led out to outside and the other end is connected to the first or second circuit elements;
a second lead connecting the first and second circuit elements; and
a third lead extending in a manner of connecting the first and second lands and formed to have a narrower width than those of the first and second lands; and
a sealing resin sealing each of the circuit elements and each of the leads.

10. The circuit device according to claim 9, wherein the first circuit element is a SAW filter.

11. The circuit device according to claim 9, wherein the second circuit element is any one of a semiconductor element for processing any one of a video signal and an image signal, a semiconductor element for processing information associated with the video signal, and a CCD for delaying an electrical signal.

12. The circuit device according to claim 9, wherein any one of the first and second circuit elements is connected to any one of the first and second leads through a fine metal wire.

13. A method of manufacturing a circuit device, comprising the steps of:
placing a first circuit element having a hollow inside and a second circuit element electrically connected to the first circuit element in a cavity of a molding die; and
sealing the first and second circuit elements with resin by filling sealing resin from a gate into the cavity,
wherein the first circuit element is located farther away from the gate than the second circuit element is.

14. The method according to claim 13,
wherein the cavity forms a long and narrow space,
the gate is formed in an end portion of the cavity in a longitudinal direction, and
the first circuit element is located in a vicinity of an end portion opposite to the gate inside the cavity.

15. The method according to claim 13, wherein thermosetting resin is adopted as the sealing resin.

16. A circuit device, comprising:
a first circuit element having a hollow therein;
a second circuit element electrically connected to the first circuit element; and
a sealing resin covering the first and second circuit elements,
wherein the first and second circuit elements are sealed by enclosing the sealing resin from a gate in a cavity molded with a mold, and a distance between the first circuit element and the gate is longer than a distance between the second circuit element and the gate.

17. The circuit device according to claim 16, wherein the gate is positioned at an edge in a lengthwise direction of the sealing resin, and the first circuit element is disposed in a vicinity of the edge opposed to the gate.

18. The circuit device according to claim 16, wherein the plurality of second circuit elements are disposed in a vicinity of a central area of the sealing resin, and the first circuit element is disposed in a more peripheral area than the second circuit elements.
